(19) United States
(12) Patent Application Publication
(10) Pub. No.: US 2011/0162705 A1
(43) Pub. Date: Jul. 7, 2011

(54) MOISTURE RESISTANT PHOTOVOLTAIC DEVICES WITH ELASTOMERIC, POLYSILOXANE PROTECTION LAYER

(76) Inventors: Paul J. Popa, Auburn, MI (US); Michelle L. Boven, Midland, MI (US); Zenon Lysenko, Midland, MI (US); Michael E. Mills, Midland, MI (US); Leonardo C. Lopez, Midland, MI (US)

(21) Appl. No.: 12/974,643

(22) Filed: Dec. 21, 2010

Related U.S. Application Data
(60) Provisional application No. 61/292,646, filed on Jan. 6, 2010.

(51) Int. Cl. H01L 31/0216

(52) U.S. Cl. 136/256

(57) ABSTRACT

Improved protection systems for CIGS-based microelectronic devices of the type incorporating electric conductor(s) such as an electronic collection grid. In one aspect, the present invention relates to a photovoltaic device having a light incident surface and a backside surface. The device includes a chalcogenide-containing photovoltaic layer comprising at least one of copper, indium and/or gallium. A transparent conductive layer is interposed between the photovoltaic layer and the light incident surface, wherein the transparent conductive layer is electrically coupled to the photovoltaic layer. An electronic collection grid is electrically coupled to the transparent conductive layer and overlying at least a portion of the transparent conductive layer. An elastomeric structure having a light incident surface, said structure overlying at least portions of the electronic collection grid and the transparent conductive layer in a manner such that the light incident surface of the elastomeric structure is spaced apart from a major portion of the conductor, and wherein the elastomeric structure comprises an elastomeric siloxane polymer having a WVTR of at least 0.1 g/m²-day. An optional protective barrier overlies the elastomeric structure. The protection systems of the invention incorporate elastomers with water vapor transmission rates that are atypically high in the context of CIGS-based devices.

### PRIORITY

The present nonprovisional patent Application claims priority under 35 U.S.C. §119(e) from U.S. Provisional patent application having Ser. No. 61/292,646, filed on Jan. 6, 2010, by Popa et al. and titled MOISTURE RESISTANT PHOTOVOLTAIC DEVICES WITH ELASTOMERIC, POLYSILOXANE PROTECTION LAYER, wherein the entirety of said provisional patent application is incorporated herein by reference.

### FIELD OF THE INVENTION

The present invention relates to photovoltaic devices of the type incorporating a conductive collection grid that facilitates ease of making external electrical connections, and more particularly to chalcogen-based photovoltaic devices in which the collection grid is contacted on at least one side by an elastomeric polysiloxane protection layer.

### BACKGROUND OF THE INVENTION

Both n-type chalcogenide compositions and/or p-type chalcogenide compositions have been incorporated into components of photovoltaic devices. The p-type chalcogenide compositions have been used as the photovoltaic absorber region in these devices. Illustrative p-type, photovoltaically active chalcogenide compositions often include sulfides and/or selenides of at least one or more of copper (Cu), indium (In), and/or gallium (Ga). More typically at least two or even all three of Cu, In, and Ga are present. Such materials are referred to as CIS, CISS, CIGS, and/or CIGSS compositions, or the like (collectively CIGS compositions hereinafter).

Absorbers based upon CIGS compositions offer several advantages. As one, these compositions have a very high cross-section for absorbing incident light. This means that a very high percentage of incident light can be captured by CIGS-based absorber layers that are very thin. For example, in many devices, CIGS-based absorber layers have a thickness in the range of from about 1 μm to about 3 μm. These thin layers allow devices incorporating these layers to be flexible. This is in contrast to crystalline silicon-based absorbers. Crystalline silicon-based absorbers have a lower cross-section for light capture and generally must be much thicker to capture the same amount of incident light. Crystalline silicon-based absorbers tend to be rigid, not flexible.

The n-type chalcogenide compositions, particularly those incorporating at least cadmium, have been used in photovoltaic devices as absorber layers. These materials generally have a band gap that is useful to help form a p-n junction proximal to the interface between the n-type and p-type materials. Like p-type materials, n-type chalcogenide layers can be thin enough to be used in flexible photovoltaic devices. These chalcogenide based photovoltaic cells frequently also include other layers such as transparent conductive layers and window layers.

To protect chalcogenide-based solar cells from detrimental moisture degradation, one or more hermetic barrier films can be deposited over the devices. Unfortunately, the photovoltaic cells based on p-type and n-type chalcogenides are water sensitive and can unduly degrade in the presence of too much water. Improved barrier strategies are desirable.

### SUMMARY OF THE INVENTION

The present invention provides improved protection systems for CIGS-based microelectronic devices of the type incorporating electric conductor(s) such as an electronic collection grid. The protection systems of the invention incorporate elastomers with water vapor transmission rates that are atypically high in the context of CIGS-based devices. Quite surprisingly, even though the elastomeric material is highly permeable to water vapor, the integrated protection system still provides excellent protection against water damage.

The protection systems are incorporated into the devices such that the protection systems are positioned over and bury at least a portion of an underlying electronic collection grid. The protection systems not only protect the devices from the environment but also include features that accommodate and protect the devices from delamination stresses. Schematically, the protection systems can be viewed as incorporating an elastomeric region that functions as a three-dimensional shock absorber to help absorb and dissipate delamination stresses.

The systems accommodate stresses very well even when the elastomeric barrier is strongly bonded to the underlying electronic grid. This is significant, because the coupling between delamination stresses and such adhesion characteristics has been problematic in the past. As a consequence of this coupling, many conventional proposals for barrier films have been generally inadequate to give long term protection needed by chalcogenide-based solar cells. On one hand, some embodiments of conventional barrier films have tended to show poor adhesion to the top surface(s) of the device. In particular, the adhesion between barrier materials and underlying conductive collection grids may not have been as strong as desired. These adhesion issues can result in undue delamination or in a rupture of the continuous hermetic barrier film and/or provide open pathways allowing water intrusion to reach the chalcogenide compositions too easily. On the other hand, if the adhesion of the barrier film to the grid is strengthened using many conventional strategies, delamination stresses may tend to propagate through the grid and cause delamination issues elsewhere in the device. In short, both good adhesion and poor adhesion between conventional barrier films and the grid have led to delamination issues, resulting in device performance degradation and ultimately failure. The present invention is significant in that use of the elastomer layer would help to decouple delamination stresses from grid adhesion, thereby allowing strong grid adhesion to be practiced with a substantially reduced risk of delamination during cell life.

In one aspect, the present invention relates to a photovoltaic device having a light incident surface and a backside surface. The device includes a chalcogenide-containing photovoltaic layer comprising at least one of copper, indium and/or gallium. A transparent conductive layer is interposed between the photovoltaic layer and the light incident surface, wherein the transparent conductive layer is electrically coupled to the photovoltaic layer. An electronic collection grid is electrically coupled to the transparent conductive layer and overlying at least a portion of the transparent conductive layer. An elastomeric structure having a light incident surface, said structure overlying at least portions of the electronic collection grid and the transparent conductive layer in a manner such that the light incident surface of the elastomeric structure is spaced apart from a major portion of the conductor, and wherein the elastomeric structure comprises an elastomeric siloxane polymer having a WVTR of at least 0.1 g/m²-day. An optional protective barrier overlies the elastomeric structure.

According to one preferred embodiment the protective barrier, if present, optionally incorporates at least one film including an inorganic metal oxide, metal carbide, and/or metal nitride.

### BRIEF DESCRIPTION OF THE DRAWINGS

The above mentioned and other advantages of the present invention, and the manner of attaining them, will become more apparent and the invention itself will be better understood by reference to the following description of the embodiments of the invention taken in conjunction with the accompanying drawings, wherein:

FIG. 1 is a schematic cross-section of one embodiment of a photovoltaic device according to principles of the present invention; and

FIG. 2a is a schematic representation of a first siloxane polymer precursor having Si-alkenyl functionality that is useful in a hydrosilylation curing scheme for forming a siloxane polymer.

FIG. 2b is a schematic representation of a second siloxane polymer precursor having silicon hydride functionality that is useful in a hydrosilylation curing scheme for forming a siloxane polymer.

FIG. 2c is a schematic representation of an alkoxy functional siloxane polymer precursor that is useful in a room temperature vulcanization curing scheme for forming a siloxane polymer.

FIG. 3 shows a preferred embodiment of a siloxane precursor with Si-alkenyl groups, wherein the precursor is suitable for use in a hydrosilylation reaction scheme.

FIG. 4 shows a preferred embodiment of a siloxane precursor with silicon hydride functionality, wherein the precursor is suitable for use in a hydrosilylation reaction scheme.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited herein are incorporated herein by reference in their respective entireties for all purposes.

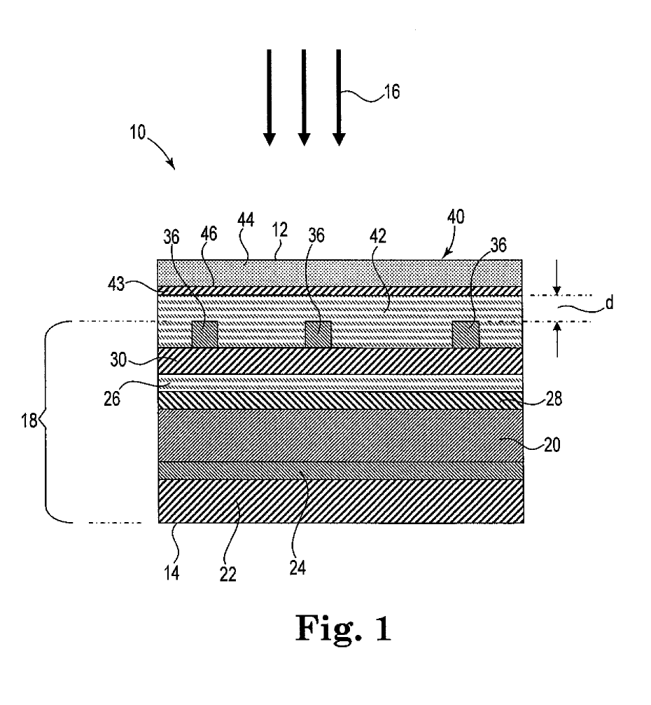

FIG. 1 schematically shows one embodiment of a photovoltaic device 10 of the present invention. Device 10 desirably is flexible to allow device 10 to be mounted to surfaces incorporating some curvature. In preferred embodiments, device 10 is sufficiently flexible to be wrapped around a mandrel having a diameter of 50 cm, preferably about 40 cm, more preferably about 25 cm without cracking at a temperature of 25° C. Device 10 includes a light incident face 12 that receives light rays 16 and a backside face 14.

Device 10 includes a substrate 18 that incorporates a chalcogenide-containing photovoltaic absorber region 20. Region 20 can be a single integral layer as illustrated or can be formed from one or more layers. The region 20 absorbs light energy embodied in the light rays 16 and then photovoltaically converts this light energy into electric energy.

The chalcogenide absorber region 20 preferably incorporates at least one IB-IIIB-chalcogenide, such as IB-IIIB-selenides, IB-IIIB-sulfides, and IB-IIIB-selenides-sulfides that include at least one of copper, indium, and/or gallium. In many embodiments, these materials are present in polycrystalline form. Advantageously, these materials exhibit excellent cross-sections for light absorption that allow region 20 to be very thin and flexible. In illustrative embodiments, a typical absorber region 20 may have a thickness in the range from about 1 μm to about 5 μm, preferably about 2 μm to about 3 μm.

Representative examples of such IB-IIIB-chalcogenides incorporate one or more of copper, indium, and/or gallium in addition to selenium and/or sulfur. Some embodiments include sulfides or selenides of copper and indium. Additional embodiments include selenides or sulfides of copper, indium, and gallium. Specific examples include but are not limited to copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGS) materials. In some embodiments, CIGS materials may include aluminum. Aluminum could be used, for instance, instead of or in addition to gallium. CIGS materials also may be doped with other materials, such as Na or the like, to enhance performance.

In representative embodiments, CIGS materials with photovoltaic properties may be represented by the formula CuIn₍₁₋ₓ₎GaₓSe_{(2-y)}S_{y} where x is 0 to 1 and y is 0 to 2. The copper indium selenides and copper indium gallium selenides are preferred. The absorber region 20 may be formed by any suitable method using a variety of one or more techniques such as evaporation, sputtering, electrodeposition, spraying, and sintering. One preferred method is co-evaporation of the constituent elements from one or more suitable targets, where the individual constituent elements are thermally evaporated on a hot surface coincidentally at the same time, sequentially, or a combination of these to form region 20. After deposition, the deposited materials may be subjected to one or more further treatments to finalize the region 20. In many embodiments, CIGS materials have p-type characteristics.

In addition to absorber region 20, substrate 18 may also include one or more other components including support 22, backside electrical contact region 24, optional window region 26, buffer region 28, and transparent conductive layer 30. As shown, each of these regions can be a single integral layer as illustrated or can be formed from one or more layers. Support 22 may be rigid or flexible, but desirably is flexible in those embodiments in which the device 10 may be used in combination with non-flat surfaces. Support 22 may be formed from a wide range of materials. These include glass, quartz, other ceramic materials, polymers, metals, metal alloys, intermetallic compositions, paper, woven or non-woven fabrics, combinations of these, and the like. Stainless steel is preferred.

The backside electrical contact region 24 provides a convenient way to electrically couple device 10 to external circuitry. Contact region 24 may be formed from a wide range of electrically conductive materials, including one or more of Cu, Mo, Ag, Al, Cr, Ni, Ti, Ta, Nb, W combinations of these, and the like. Conductive compositions incorporating Mo may be used in an illustrative embodiment. The backside electrical contact region 24 also helps to isolate the absorber region 20 from the support to minimize migration of support constituents into the absorber layer. For instance, backside electrical contact region 24 can help to block the migration of Fe and Ni constituents of a stainless steel support 22 into the absorber region 20. The backside electrical contact region 24 also can protect the support 22 such as by protecting against Se if Se is used in the formation of absorber region 20.

Optional layers (not shown) may be used adjacent the electric contact region 24 in accordance with conventional practices now known or hereafter developed to help enhance adhesion between backside electrical contact region 24 and the support 22 and/or between backside electrical contact region 24 and the absorber region 20. Additionally, one or more barrier layers (not shown) also may be provided over the face 14 to help isolate device 10 from the ambient and/or to electrically isolate device 10. One or more of such additional layers (not shown) also may be incorporated into device 10 for a variety of other reasons, including to help prevent selenization of the substrate during fabrication of the cell.

When based upon chalcogenide materials, the device 10 often is provided with a heterojunction structure. This is in contrast to silicon-based semiconductor cells that typically have a homojunction structure. A heterojunction may be formed between the absorber region 20 and the transparent conductive layer 30. The heterojunction is buffered by buffer region 28. An optional window region 26 also may be present as a component of substrate 18. Each of these regions is shown as a single integral layer, but can be a single integral layer as illustrated or can be formed from one or more layers.

Buffer region 28 generally comprises an n-type semiconductor material with a suitable band gap to help form a p-n junction proximal to the interface 32 between the absorber region 20 and the buffer region 28. Suitable band gaps for the buffer region 28 generally are in the range from about 1.7 eV to about 3.6 eV when the absorber layer is a CIGS material having a band gap in the range from about 1.0 to about 1.6 eV. CdS has a band gap of about 2.4 eV. Illustrative embodiments of buffer region 28 generally may have a thickness in the range from about 10 nm to about 200 nm.

A wide range of n-type semiconductor materials may be used to form buffer region 28. Illustrative materials include selenides, sulfides, and/or oxides of one or more of cadmium, zinc, lead, indium, tin, combinations of these and the like, optionally doped with materials including one or more of fluorine, sodium, combinations of these and the like. In some illustrative embodiments, buffer region 28 is a selenide and/or sulfide including cadmium and optionally at least one other metal such as zinc. Other illustrative embodiments would include sulfides and/or selenides of zinc. Additional illustrative embodiments may incorporate oxides of tin doped with material(s) such as fluorine. Buffer region 28 can be formed by a wide range of methods, such as for example, chemical bath deposition, partial electrolyte treatment, evaporation, sputtering, or other deposition technique.

Optional window region 26 can help to protect against shunts. Window region 26 also may protect buffer region 28 during subsequent deposition of the transparent conductive layer 30. The window region 26 may be formed from a wide range of materials and often is formed from a resistive, transparent oxide such as an oxide of Zn, In, Cd, Sn, combinations of these and the like. An exemplary window material is intrinsic ZnO. A typical window region 26 may have a thickness in the range from about 10 nm to about 200 nm, preferably about 50 nm to about 150 nm, more preferably about 80 nm to about 120 nm.

One or more electrical conductors are incorporated into the device 10 for the collection of current generated by the absorber region 20. A wide range of electrical conductors may be used. Generally, electrical conductors are included on both the backside and light incident side of the absorber region 20 in order to complete the desired electric circuit. On the backside, for example, backside electrical contact region 24 provides a backside electrical contact in representative embodiments. On the light incident side of absorber region 20 in representative embodiments, device 10 incorporates a transparent conductive layer 30 and collection grid 36. Optionally an electrically conductive ribbon (not shown) may also be used to electrically couple collection grid 36 to external electrical connections.

The transparent conductive layer 30 is a component of substrate 18 and is interposed between the buffer region 28 and light incident surface 12. Transparent conductive layer 30 is electrically coupled to the buffer region 28 to provide a top conductive electrode for substrate 18. In many suitable embodiments, the transparent conductive layer 30 has a thickness in the range from about 10 nm to about 1500 nm, preferably about 150 nm to about 200 nm. As shown, the transparent conductive layer 30 is in contact with the window region 26. As an example of another option, transparent conductive layer 30 might be in direct contact with the buffer region 28. One or more other kinds of intervening layers optionally may be interposed for a variety of reasons such as to promote adhesion, enhance electrical performance, or the like.

The transparent conductive layer 30 may be a very thin metal film (e.g., a metal film having a thickness in the range from about 5 nm to about 200 nm, preferably from about 30 nm to about 100 nm, in representative embodiments so that the resultant films are sufficiently transparent to allow incident light to reach the absorber region 20) but is preferably a transparent conductive oxide. As used herein, the term “metal” refers not only to metals, but also to metal admixtures such as alloys, intermetallic compositions, combinations of these, and the like. These metal compositions optionally may be doped. Examples of metals that could be used to form thin, optically transparent layers 30 include the metals suitable for use in the backside contact region 24, combinations of these, and the like.

As an alternative to metals or in combination with metals, a wide variety of transparent conducting oxides or combinations of these may be incorporated into the transparent conductive layer 30. Examples include fluorine-doped tin oxide, tin oxide, indium oxide, indium tin oxide (ITO), aluminum doped zinc oxide (AZO), zinc oxide, combinations of these, and the like. In one illustrative embodiment, the transparent conductive layer 30 is indium tin oxide. TCO layers are conveniently formed via sputtering or other suitable deposition technique.

Electrically conductive collection grid 36 also is a component of the substrate 18 for purposes of the present invention. Electrical grid 36 can be formed from ingredients that include a wide range of electrically conducting materials, but most desirably are formed from one or more metals, metal alloys, or intermetallic compositions. Exemplary contact materials include one or more of Ag, Al, Cu, Cr, Ni, Ti, combinations of these, and the like. In one illustrative embodiment, the grid 36 has a dual layer construction (not shown) comprising nickel and silver. A first layer of Ni is deposited to help enhance the adhesion of a second layer of Ag to the substrate 18. Advantageously, the present invention helps to protect against delamination stresses, and consequently the adhesion of the grid 36 to the underlying substrate components can be enhanced without undue risk that the improved adhesion would be too problematic.

Because such conductive materials generally tend to be opaque, they are deposited as a grid of spaced apart lines so that the grid occupies a relatively small footprint on the surface (e.g., in some embodiments, the grid occupies about 5% or less, even about 2% or less, or even about 1% or less of the total surface area associated with light capture to allow the photoactive materials to be exposed to incident light). Desirably, an interconnection system (not shown) is used to provide electrical connection between the grid 36 and external electronic circuitry. Such a system, for instance, can be used to help sum the electrical output of a plurality of photovoltaic devices within or between one or more panels. In many embodiments, this system includes an electrically conductive ribbon (often tine coated copper (e.g. 1 mm×3 to 5 mm) that is used to interconnect a plurality of devices in series and/or parallel fashion. As an alternative to this kind of system, other approaches may be used. For example, an alternative approach is to singulate the continuously deposited bottom conductor; photovoltaic absorber material, buffer material, and top transparent conductor material but retain the continuous deposition substrate.

A protective barrier system 40 is provided on the substrate 18. The protective barrier system 40 is positioned over the electronic grid 36. The barrier system 40 helps to isolate and protect the substrate 18 from the environment, including protection against water degradation. The barrier system also incorporates features that help to reduce the risk of damage to device 10 due to delamination stresses, such as might be caused by thermal cycling and or localized stress such as might be caused by impact from hail and or localized point load from the weight of an installer or dropped tools during installation. Schematically, these features act like a three-dimensional shock absorber to help absorb and dissipate internal delamination stresses. The propagation of delamination stresses is substantially inhibited as a result; thereby making embodiments of the invention such as device 10 are more robust.

The protective barrier system 40 includes at least two components in many embodiments. A first component is elastomeric structure 42 positioned proximal to the electronic grid 36, and an optional second component is protective barrier 44 distal from grid 36. As shown in FIG. 1 with respect to a preferred aspect, elastomeric structure 42 is directly adjacent and adhered to the underlying grid 36 without an intervening layer. Optionally, though, one or more additional layers 43, e.g., a tie layer for instance, may be interposed between elastomeric structure 42 and the underlying grid 36 if desired. Also as shown, elastomeric structure 42 is shown as a single integral layer, but structure 42 may also be formed from a plurality of layers (not shown) in other embodiments.

With regard to the illustrative embodiment of device 10 shown in FIG. 1, note that each of the grid components of electronic grid 36 is located at an independent depth d below the interface between elastomeric structure 42 and the protective barrier 44. In this way, the light incident surface 46 of the elastomeric structure is spaced apart from the grid 36 to create a volume of elastomeric cushioning between the grid 36 and the surface 46 in three dimensions. Even though this depth d is interposed between the grid 36 and the overlying surface 46, this elastomeric cushioning effect of the structure 42 protects the grid 36 from delaminating stresses that might originate from sources within device 10 that are above and/or below the grid 36 and or delaminating stresses that might originate from sources above or below the elastomeric structure 42.

Generally, the depth d for each grid component independently is selected to be sufficient to allow the elastomeric structure 42 to help protect and isolate the electronic grid 36 from the transmission of delaminating stresses originating in the device 10 such as from substrate 18 below the grid 36 and/or in the protective barrier 44 and other optional layers (not shown), if any, that might be provided over the protective barrier 44. A suitable depth d can vary over a wide range. If the depth d is too small, though, the elastomeric structure 42 might not help isolate and protect the grid 36 from delaminating stresses as much as might be desired. If too thick, then there could be an increased probability that air could be trapped or voids could form in the elastomeric structure during cure. Balancing these concerns, representative embodiments of device 10 may be characterized by a depth d in the range from 0.5 mil to about 50 mils, preferably from 1 mils to about 20 mils. In illustrative embodiments, siloxane layers having thicknesses of about 3 mils and 17 mils, respectively, were found to be suitable.

As used herein, an elastomer is a material that substantially returns to its original shape when a deforming force is removed. Preferred elastomers also have an elongation at break at 25° C. of at least about 25%, preferably at least about 50%, and more preferably at least about 100% according to ASTM D412 (2006) By way of example, the polysiloxane polymer that is formed from the commercially available Sylgard 184 product (described in more detail below) has an elongation at break of about 100% at about 25° C. This polysiloxane polymer is suitable for forming an elastomeric structure using principles of the present invention. The terminology “elastomer” encompasses thermoplastic, thermosetting, and/or thermoset polymers having this set of elastomeric characteristics, although thermoset elastomers are more common.

More preferably, a material will be deemed to be elastomeric if a sample of the material that is three inches long, 0.25 inches wide and 0.0625 inches thick can return to a length in the range of from about 2.4 inches to about 3.9 inches, preferably about 2.8 inches to about 3.2 inches in a time period under about 30 seconds, preferably under about 10 seconds, more preferably under about 2 seconds when the deforming force is removed after the sample is stretched at 25° C. to 3.5 inches, preferably 3.75 inches, more preferably 4.5 inches.

Elastomeric materials may have a hardness in a wide range. However, if the material is too hard, then the material may be too stiff to accommodate thermal stresses that could lead to delamination of device layers. Additionally, if the material is too hard it would not be able to dissipate stresses that originate in the device from the substrates above and/or below. If too soft, then the layer may lack sufficient durability and/or may not dissipate stresses as much as might as might be desired. Balancing these concerns, illustrative elastomeric materials have a Shore A hardness (durometer) in the range from about 15 to about 75, preferably about 20 to about 65, more preferably about 25 to about 50 according to ASTM D2240 (2005).

The elastomeric structure 42 includes at least one elastomeric, siloxane polymer (also referred to herein as a polysiloxane polymer) having a water vapor transmission rate (WVTR) of at least about 0.1 g/m²-day, preferably at least about 2 g/m²-day, more preferably at least about 10 g/m²-day. At the high end, the upper limit on the WVTR is subject to practical concerns such as maintaining good wet adhesion so that the resultant device demonstrates performance to meet desired specifications for water sensitivity. As general guidelines, the upper limit for WVTR of many embodiments might be up to about 500 g/m²-day, preferably up to about 350 g/m²-day, more preferably up to about 150 g/m²-day.

The water vapor transmission rate (sometimes also referred to as the moisture vapor transmission rate or MVTR) is a measure of the rate at which water vapor passes through a material. In the practice of the present invention, the WVTR of a siloxane polymer is determined according to the methodology described in ASTM F1249 (2006). WVTR data conveniently is collected at 38° C. and 50° C.

A variety of siloxane polymers or precursors thereof are commercially available. In many instances, the commercial products are supplied as multi-part kits in which the parts are combined and mixed just prior to use. The combined admixture then reacts to form the siloxane polymer in situ. By way of illustration, the siloxane polymer precursor product commercially available from Dow Corning under the trade designation DC 3-1765 cures to provide a siloxane polymer that has a WVTR of about 76 to 78 g/m²-day when tested at 38° C. and 100% humidity and a WVTR of about 123 to 127 g/m²-day when tested at 50° C. and 100% humidity. As another example, the siloxane polymer precursor product commercially available from Dow Corning under the trade designation Sylgard 184 cures to provide a siloxane polymer that has a WVTR of about 57 to 58 g/m²-day when tested at 38° C. and 100% humidity and a WVTR of about 96 to 97 g/m²-day when tested at 50° C. and 100% humidity.

In the context of a CIGS-based solar cell, such WVTR characteristics are extremely high. These WVTR characteristics are at least 10,000 times greater, and even 10⁶ times greater than the rates that conventional wisdom has deemed to be acceptable for encapsulants used to protect CIGS devices. Due to the water sensitivity of CIGS based cells, there has been a conventional understanding to avoid using barrier materials for which the WVTR is greater than about 10⁻⁴ g/m²-day (measured at 38° C.), and even more strictly to avoid using barrier materials for which the WVTR is greater than about 10⁻⁶ g/m²-day (measured at 38° C.). The conventional wisdom would have tended to create an expectation that the water-sensitive absorber and buffer layers of the cell otherwise would be too vulnerable to the water vapor that can easily migrate through materials with higher WVTR characteristics. Note that this negative bias has been generally inapplicable to silicon-based cells inasmuch as silicon has significantly less water sensitivity in comparison to CIGS materials.

The present inventors have discovered that CIGS-based cells incorporating relatively high WVTR materials surprisingly not only show improved resistance to delamination stresses but also are highly resistant to water degradation. This result is counterintuitive. Common intuition might suggest that the siloxane polymers seemingly would provide an easy path for water to penetrate into the cell and damage water sensitive cell components. While not wishing to be bound, a possible theory to explain why a high level of water resistance is maintained when using such siloxane polymers can be suggested. Firstly, even though water vapor might possibly be able to penetrate into the siloxane material readily, the dry and wet adhesion at the interfaces between the siloxane material and adjacent cell components is of sufficiently high quality that liquid water is unable to pool to an undue degree at these interfaces. In other words, the interfaces are still protected against liquid water. Secondly, it is also believed that a major factor contributing to moisture degradation in a cell are corrosion mechanisms when liquid water is present. Consequently, even though the siloxane material is highly permeable to water vapor, the interfaces between this material and other cell components is of such high quality that liquid water pooling is prevented. Corrosion is substantially reduced as a consequence. Beneficially, many embodiments of elastomeric siloxane polymers are transparent, flexible, hydrophobic, and weatherable. These materials also tend to be stable to UV exposure and show good wet and dry adhesion to the kinds of materials used in photovoltaic devices. A siloxane polymer refers to a polymer whose backbone includes at least one siloxane repeating unit in which the backbone of the repeating unit comprises at least one silicon atom adjacent to a backbone oxygen atom (hereinafter siloxane repeating unit). A chain of siloxane repeating units forms a backbone of alternating Si and O atoms siloxane In addition to siloxane repeat units, a siloxane polymer optionally may incorporate one or more other kinds of repeating units. However, if the content of these other blocks is too high, the elastomeric and/or adhesion characteristics could be less than might be desired. The different kinds of siloxane and other kinds (if any) of repeating units may be incorporated into the polymer randomly and/or in blocks.

Elastomeric structures 42 incorporating siloxane polymers can be provided in a variety of ways. An illustrative technique forms a siloxane polymer-containing structure in situ by appropriately mixing and co-applying suitable precursors onto the substrate 18. After being applied, the precursors are allowed and/or caused to polymerize to form the desired siloxane polymer-based structure 42. Exemplary precursors can be cured using a variety of curing strategies. For instance, two representative curing strategies include hydrosilylation curing techniques and/or hydrolysis/condensation of alkoxy groups with moisture. Hydrosilylation curing techniques may be more preferred in some instances inasmuch as hydrosilylation curing occurs at a faster rate than room temperature vulcanization schemes (room temperature vulcanization schemes are also referred to herein as moisture/alkoxy reactions).

There are a wide range of commercially available precursor products that can be used to form siloxane polymers in situ on substrate 18. For example, each of the Sylgard® 184 Silicone Elastomer Kit and SE 1740 materials from Dow Corning is a 2 part, solventless, combination of suitable precursors that cure without generating by-products. The Sylgard® 184 product can be cured at a variety of temperatures, such as either at room temperature or thermally to increase the curing rate. The SE 1740 product generally benefits from a thermal cure. The 3-1765 Conformal Coating product from Dow Corning is a solventless silicone, room temperature vulcanizable (RTV) coating. The material cures via hydrolysis/condensation of alkoxy groups via atmospheric moisture.

A representative hydrosilylation curing scheme involves reacting a first precursor comprising at least two Si-alkenyl moieties with a second precursor comprising at least two co-reactive silicon hydride moieties. The reaction provides an elastomeric siloxane polymer product. The precursors used in actual practice may have any kind of backbone structure and are not limited to linear structures. For instance, the precursor backbones may incorporate not only linear but also branched, and/or cyclic portions.

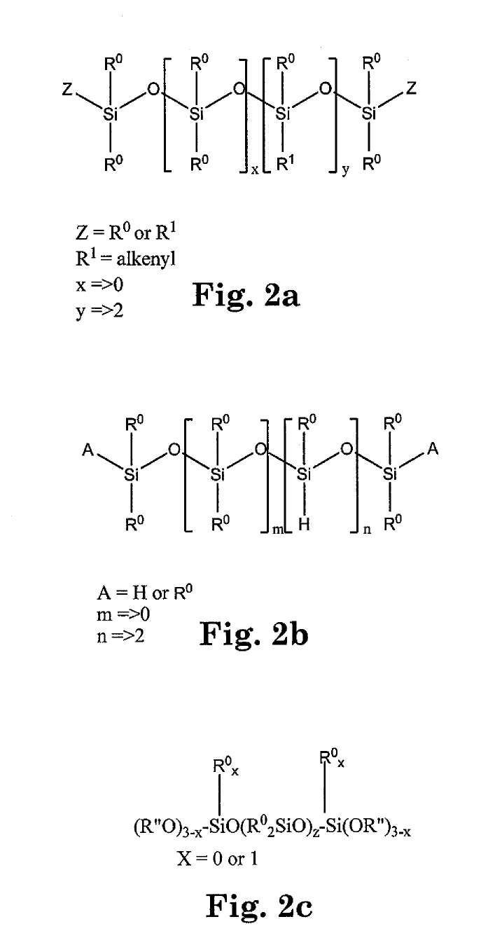

One representative embodiment of a first precursor has the formula according to FIG. 2a, wherein each R⁰ independently is linear, branched, and/or cyclic, monovalent moiety or co-member of a ring structure with another R⁰ or Z that is compatible with the hydrosilylation reaction. Preferably, each R⁰ independently is an aliphatic or aromatic hydrocarbyl moiety and/or alkoxy moiety including from 1 to 20, preferably 1 to 10, more preferably 1 to 3, and most preferably 1 carbon atom. Use of embodiments in which each R⁰ independently is linear, branched, or cyclic alkyl such as methyl, ethyl, propyl, isopropyl, butyl, isobutyl, hexyl, cyclohexyl, combinations of these, and the like, would be more suitable. Methyl and ethyl groups are preferred. Methyl groups are most preferred. Each alkenyl group, R¹, independently has from 2 to 10 carbon atoms and includes at least one carbon-carbon double bond. Examples of R1 include but are not limited to vinyl, allyl, allyloxy, hexenyl, combinations of these, and the like. Each Z independently may be R⁰ or R¹, and preferably is R¹.

In addition to the siloxane repeating units, the first precursor optionally may include one or more other kinds of repeating units, such as polyurethane, polyester, polyether, polyvinyl, polyolefin, polyamide, polyimide, sulfone, combinations of these, and the like. The additional repeating unit(s), if any, may be aliphatic or aromatic, but preferably are aliphatic for outdoor weatherability. If too much of such additional repeating unit(s) are used, though, the elastomeric, WVTR, transparency, and/or adhesion properties of the resultant siloxane polymer could suffer. Accordingly, the content of such additional repeating units desirably is limited so that such repeating units constitutes no more than 10 molar percent, preferably no more than 5 molar percent, more preferably no more than 0.5 molar percent, and even 0 molar percent of the first precursor. The different kinds of siloxane and other kinds (if any) of repeating units may be incorporated into the first precursor randomly and/or in blocks.

The relative molar amounts of the different siloxane repeating units incorporated into the first precursor are denoted by the subscripts x and y. As general guidelines, x is 0 or greater, and y is at least 2. However, if y is high relative to the sum of x and y, then the crosslink density of the resultant product could be too high, and the product may not be as elastomeric as might be desired. Accordingly, it is preferred that y is limited so that corresponding repeating unit containing alkenyl functionality constitutes no more than about 50 molar percent, more preferably about 20 molar percent of the first precursor.

The maximum value for x can vary over a wide range. The maximum value of x is subject to mostly practical concerns. If the sum of x and y is too high, the viscosity of the first precursor might be too high to be compatible with the desired application technique. Also, the crosslink density of the resultant product might be too low to provide the product with desired characteristics. Balancing such concerns, and taking into account the value for y, it is desirably that x has a maximum value such that the first precursor has a formulation viscosity in the range from about 5 to about 50,000 mPa-sec (centipoise); preferably from about 25 to about 20,000 mPa-sec; and most preferably from about 150 to about 5,000 mPa-sec. To determine formulation viscosity, the material is formulated according to the supplier's directions if appropriate, and the viscosity is measured according to ASTM D2196 (2005). It is believed that a first precursor having such characteristics would have a weight average molecular weight in the range from about 300 to about 50,000 more preferably about 300 to about 25,000, even more preferably about 300 to about 15,000. Resultant elastomers prepared from such precursors may have a weight average molecular weight in the range from about 25,000 to 1,000,000, preferably about 50,000 to about 200,000, and more preferably about 80,000 to 120,000.

One representative embodiment of a second precursor including silicon hydride functionality has the formula according to FIG. 2b, wherein each R⁰ independently is a linear, branched, and/or cyclic monovalent moiety or a co-member of a ring structure with another R⁰ or A that is compatible with the hydrosilylation reaction. Preferably, each R⁰ is an aliphatic or aromatic hydrocarbyl moiety and/or alkoxy moiety including from 1 to 20, preferably 1 to 10, more preferably 1 to 3, and most preferably 1 carbon atom. Use of embodiments in which each R⁰ independently is linear, branched, or cyclic alkyl such as methyl, ethyl, propyl, isopropyl, butyl, isobutyl, hexyl, cyclohexyl, combinations of these, and the like, would be suitable. Methyl and ethyl groups are preferred. Methyl groups are most preferred.

In addition to the siloxane repeating units the second precursor optionally may include one or more other kinds of repeating units, such as polyurethane, polyester, polyether, polyvinyl, polyolefin, polyamide, polyimide, sulfone, combinations of these, and the like. The additional repeating unit(s), if any, may be aliphatic or aromatic, but preferably are aliphatic for outdoor weatherability. If too much of such additional repeating unit(s) are used, though, the elastomeric, WVTR, transparency, and/or adhesion properties of the resultant siloxane polymer could suffer. Accordingly, the content of such additional repeating units in the second precursor desirably is limited so that such repeating units constitutes no more than 10 molar percent, preferably no more than 5 molar percent, more preferably no more than 0.5 molar percent, and even 0 molar percent of the first precursor. The different kinds of siloxane and other kinds (if any) of repeating units may be incorporated into the second precursor randomly and/or in blocks.

The relative amounts of the different siloxane repeating units incorporated into the second precursor are denoted by the subscripts m and n. As general guidelines, m is 0 or greater n is 2 or greater.

The maximum value of m is subject to mostly practical concerns. If the sum of m and n is too high, the viscosity of the second precursor might be too high to be compatible with the desired application technique. Also, the crosslink density of the resultant siloxane polymer product might be too low to provide the product with desired characteristics. Balancing such concerns, and taking into account the desired value for n, it is desirably that m has a maximum value such that the second precursor has a formulation viscosity in the range from about 50 to about 50,000 mPa-sec (centipoise); preferably from about 100 to about 20,000 mPa-sec; and most preferably from about 150 to about 5,000 mPa-sec. It is believed that a first precursor having such characteristics would have a weight average molecular weight in the range from about 300 to about 100,000, more preferably about 300 to about 50,000, even more preferably about 300 to about 25,000. Resultant elastomers prepared from such precursors may have a weight average molecular weight in the range from about 25,000 to 1,000,000, preferably about 50,000 to about 200,000, and more preferably about 80,000 to 120,000. Additionally, if n is high relative to the sum of m and p, then the crosslink density of the resultant siloxane polymer product could be too high, and the product may not be as elastomeric as might be desired. Accordingly, it is preferred that n is limited so that repeating unit 114 constitutes no more than about 70 molar percent, more preferably about 20 molar percent of the second precursor.

The hydrosilylation reaction scheme yields a siloxane polymer product in which the residues of the first and second precursors are linked via divalent moiety resulting from the reaction between the Si-alkenyl functionality and the silicon hydride functionality. The reaction scheme can be carried out at a wide variety of temperatures. The reactants can be chilled, heated, or used at room temperature, for instance. In many embodiments, carrying out the reaction at room temperature would be suitable. In other embodiments, carrying out the reaction with moderate heating may be used to increase the reaction rate. Conveniently, the reaction may be carried out in ambient air at ambient pressure.

The reaction scheme may be carried out in the presence of an effective amount of a suitable hydrosilylation catalyst. Representative catalyst embodiments may incorporate one or more of platinum, rhodium, iridium, palladium, ruthenium, catalytically active gold, combinations of these, and the like. The amount of catalyst used may vary over a wide range. As general guidelines, using from about 0.001 to about 1000 parts by weight of catalyst per 100,000 to 2,000,000 parts by weight of the total amount of precursors 102 and 104 would be suitable.

In practice, the reaction ingredients are combined proximal to the time of use to form a suitable admixture that can then be applied in liquid form onto substrate 18 using an appropriate application method including spraying, brushing, pouring, spin coating, roll coating, dipping, or the like. The viscosity of the admixture should be compatible with the desired application technique. It is also desirable that the viscosity and other rheological characteristics allow the admixture to self level in a short time after being dispensed. As general guidelines, using an admixture with a viscosity in the range from about 10 mPa-s to about 2000 mPa-s, preferably about 50 to 300 mPa-s, more preferably about 100 to about 200 mPa-s, measured at 25° C. would be suitable. The rheology or viscosity of the material can be modified through the use of solvents. Dry, aprotic solvents are very desirably when using siloxane precursors with alkoxy groups to avoid undesired interaction between these groups and the solvent. Examples of suitable aprotic solvents but not limited to include aliphatic hydrocarbons (hexane, heptane, paraffinic solvents such as Isopar G, mineral spirits, etc); aromatic hydrocarbons (toluene, xylene, etc); alkyl aromatics (ethyl benzene, propyl benzene, etc) chlorinated solvents (methylene chloride, trichloroethane); propionates (n-butyl propionate, n-propyl propionate, etc); ketones (cyclohexanone, MEK, MIBK, etc).

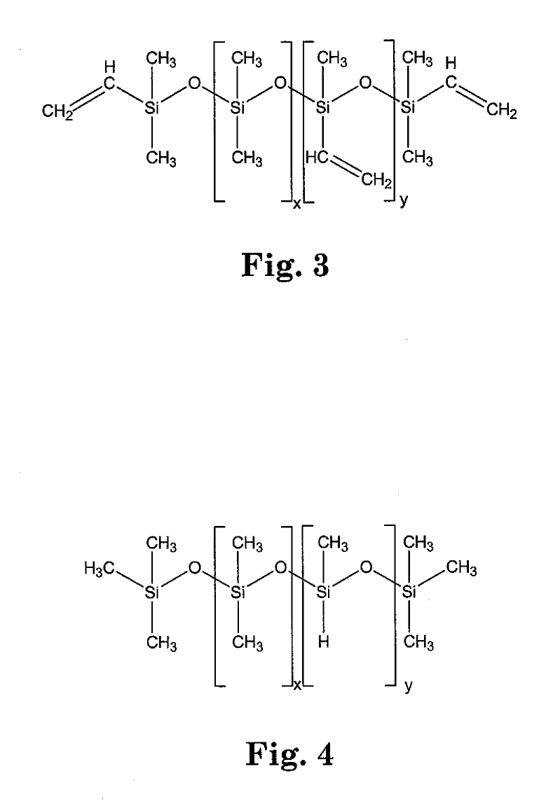

FIG. 3 shows a preferred embodiment of a siloxane precursor having Si-alkenyl functionality that can be used as all or part of the first precursor 102 of FIG. 2. FIG. 4 shows a preferred embodiment of a siloxane precursor having silicon hydride functionality that can be used as all or a portion of precursor 104 of FIG. 2.

As an alternative to hydrosilylation curing schemes, siloxane polymers can also be formed via room temperature vulcanization (RTV) under which one or more alkoxy functional siloxane precursors cure by reacting with moisture to form siloxane polymers. An exemplary alkoxy functional siloxane has the formula shown in FIG. 2c, wherein each x independently is 0 or 1, and each R⁰ independently is a linear, branched, and/or cyclic monovalent moiety or co-member of a ring structure with another R⁰. Preferably, each R⁰ independently is an aliphatic or aromatic hydrocarbyl moiety and/or alkoxy moiety including from 1 to 20, preferably 1 to 10, more preferably 1 to 3, and most preferably 1 carbon atom. Use of embodiments in which each R⁰ is linear, branched, or cyclic alkyl such as methyl, ethyl, propyl, isopropyl, butyl, isobutyl, hexyl, cyclohexyl, combinations of these, and the like, would be suitable. Methyl and ethyl groups are preferred. Methyl groups are most preferred.

Each R″ independently is R⁰ or is a monovalent aliphatic hydrocarbon radical with less than 5 carbons, such as but not limited to, methyl, ethyl, propyl, and butyl. Methyl and ethyl are preferred and most preferably methyl.

In addition to the siloxane repeating units the siloxane precursor of FIG. 2c optionally may include one or more other kinds of repeating units, such as polyurethane, polyester, polyether, polyvinyl, polyolefin, polyamide, polyimide, sulfone, combinations of these, and the like. The additional repeating unit(s), if any, may be aliphatic or aromatic, but preferably are aliphatic for outdoor weatherability. If too much of such additional repeating unit(s) are used, though, the elastomeric, WVTR, transparency, and/or adhesion properties of the resultant siloxane polymer could suffer. Accordingly, the content of such additional repeating units in the second precursor desirably is limited so that such repeating units constitutes no more than 10 molar percent, preferably no more than 5 molar percent, more preferably no more than 0.5 molar percent, and even 0 molar percent of the first precursor. The different kinds of siloxane and other kinds (if any) of repeating units may be incorporated into the second precursor randomly and/or in blocks.

Referring again to FIG. 1, optional protective barrier 44 is provided over the elastomeric structure 42. Optionally, the resultant elastomeric structure 42 can be planarized if appropriate before additional layers or features such as barrier 44 would be incorporated into device 10. As shown, protective barrier 44 is a single layer, but protective barrier 44 can be formed from multiple layers if desired. Additionally, FIG. 1 shows that protective barrier 44 is formed directly on the underlying elastomeric structure 42. In other embodiments, one or more additional layers (not shown) could be interposed between the structure elastomeric structure 42 and protective barrier 44 if desired. Such additional layers may be tie layers to enhance adhesion, additional protection layers to further improve the moisture barrier above the cell, provide UV blocking, offer impact resistance, provide refractive index matching or minimize the refractive index mismatch, and/or combinations of these, and the like.

According to preferred modes of practice, protective barrier 44 is formed from one or more ingredients and/or layers wherein at least one ingredient and/or layer is a dielectric, inorganic composition that has a sufficiently low dielectric constant so that protective barrier 44 helps to electrically isolate TCO coating 30 from the ambient environment except in those locations where electric contact is desired through electrical contacts (not shown) to electrically conductive grid 36. In many embodiments, protective barrier 44 has a dielectric constant in the range of 2 to about 120, preferably 2 to about 50, more preferably 3 to about 10. Additionally, protective barrier 44 also desirably provides barrier protection against water vapor intrusion. In many embodiments, protective barrier 44 is characterized by a water vapor transmission rate (WVTR) in the range of 10⁰ to about 10⁻⁵ g/m²·day, but is most preferably less than 5×10⁻⁴ g/m²·day at 85° C. and 85% relative humidity. Additionally, the barrier coatings useful in this invention preferably exhibit optical transmittance ≧80% in the transmission wavelength range from about 350 nm to about 1300 nm and more preferably exhibit ≧85% transmission in the same range.

A dielectric barrier coating useful as all or a portion of barrier 44 may have a wide range of thicknesses. If too thin, then the electric insulating properties and protection against moisture intrusion may not be as robust as might be desired. If too thick, then transparency may unduly suffer without providing sufficient extra performance. Balancing these concerns, illustrative embodiments of dielectric layers may have a thickness in the range of 10 nm to about 1000 nm, preferably about 10 nm to about 250 nm, more preferably about 50 nm to about 150 nm.

The dielectric, inorganic material(s) used to form all or a portion of protective barrier 44 can be selected from one or more metal oxides, carbides, nitrides and the like or combinations thereof. In one preferred embodiment, the barrier material is an oxide, carbide and/or nitride of silicon. These embodiments provide excellent dielectric and moisture protection. In some embodiments, protective barrier 44 preferably is formed from silicon nitride or a material incorporating silicon, nitrogen, and oxygen (a silicon oxy nitride). In other embodiments in which protective barrier 44 is formed from two or more sublayers, a first sublayer may be formed from silicon nitride, and a second sublayer may be formed from a silicon oxy nitride. When two or more sublayers are used, it is preferred that the bottom layer (i.e., the layer in contact with the TCO layer) be silicon nitride. Compounds of aluminum also may be used to form all or a portion of the protective barrier 44.

Representative embodiments of silicon nitride may be represented by the formula SiNₓ, and representative embodiments of silicon oxy nitride may be represented by the formula SiO_{y}N_{z}, wherein x is in the range from about 1.2 to about 1.5, preferably about 1.3 to about 1.4; y is preferably in the range from greater than 0 to about 0.8, preferably from about 0.1 to about 0.5; and z is in the range from about 0.8 to about 1.4, preferably about 1.0 to about 1.3. Desirably, x, y, and z are selected so that the barrier coating 34, or each sublayer thereof as appropriate, has a refractive index in the range from about 1.80 to about 3. As an example of one suitable embodiment, silicon nitride of the formula SiN_{1.3} and having a refractive index of 2.03 would be suitable in the practice of the present invention.

The protective barrier 44 can be formed in a variety of ways. According to one representative methodology in which the barrier 44 is formed predominantly from an inorganic dielectric composition, the protective barrier 44 may be deposited on the solar cell by a low temperature method carried out at less than about 200° C., preferably less than about 150° C., more preferably less than about 100° C. The temperature in this context refers to the temperature at the surface where deposition is occurring. Preferably, the inorganic barrier is deposited via magnetron sputtering. Where a preferred silicon nitride layer is to be formed, the dielectric barrier layer preferably is deposited via reactive magnetron sputtering using a silicon target and a mixture of nitrogen and argon gas. The mole fraction of nitrogen in the gas feed is preferably more than 0.1, more preferably more than 0.2 and preferably less than 1.0, more preferably less than 0.5. Prior to the deposition, a suitable base pressure in the chamber is in the range from about 1×10⁻⁸ to about 1×10⁻⁵ Torr. The operating pressure at which sputtering occurs desirably is in the range from about 2 mTorr to about 10 mTorr.

When these sputtering conditions are used to form protective barrier 44, it is believed that an interstitial, relatively thin sublayer (not shown) desirably forms proximal to the interface between TCO region 30 and the protective barrier 44. A thicker dielectric sublayer (not shown) of the protective barrier 44 forms above that. Based on the contrast difference shown in scanning electron microscopy (SEM) analysis, it is believed that the interstitial sublayer appears to be of lower density compared to the bulk of coating 34. Characterization of the elemental composition of the interstitial sublayer may tend to have an oxygen content greater than that in the bulk of coating 34. Without wishing to be bound it is postulated that the formation of this interstitial sublayer may be beneficial to the environmental barrier properties of the coating 34 and also may facilitate the reduction/healing of lattice defects caused by excessive electron and ion bombardment during film formation. This methodology of using a low temperature process to deposit the protective barrier 44 is further described in Assignee's co-pending application filed in the names of DeGroot et al. for METHOD OF FORMING A PROTECTIVE LAYER ON THIN-FILM PHOTOVOLTAIC ARTICLES AND ARTICLES MADE WITH SUCH LAYER on Mar. 25, 2009, and bearing Attorney Docket No. 67695, which is incorporated herein by reference in its entirety for all purposes.

Preferred embodiments of the protective barrier 44 exhibit optical transmittance ≧80% in the transmission wavelength range from about 400 nm to about 1300 nm and preferably exhibit ≧85% transmission in the same range. Additionally, preferred embodiments of the protective barrier 44 may exhibit a water vapor transmission rate less than 1×10⁻² g/m²·day and preferably less than 5×10⁻⁴ g/m²·day. The protective barrier 44 can be applied as a single layer or as multiple sublayers.

An optional region (not shown) may include one or more additional barrier layers provided over the protective barrier 44 to help further protect device 10. In many modes of practice, these additional barrier layers, if any, are incorporated into device 10 after desired electrical connections are made to grid 36. If such an upper film were to be formed from a dielectric or other insulating materials, the upper film can be formed after electrical contacts are made to grid 36. Alternatively, the upper film can be formed prior to making electrical connections in a manner that leaves appropriate vias available to make desired electrical connections.

As an option, an embodiment of protective barrier 44 formed predominantly from an inorganic dielectric composition also may be prepared by other methodologies, including but not limited to low temperature vacuum methods known to those skilled in the art including chemical vapor deposition (CVD), plasma-enhanced chemical vapor deposition (PECVD), atomic layer deposition (ALD) and others.

Protective barrier 44 also may be formed by lamination from single or multiple layer sheets. More than one sheet may be used. Tie layers optionally may be used to enhance adhesion of the sheets to the underlying or overlying cell layers or to other sheets of the barrier structure 44. Thermoplastic polyolefins such as the 400 micron thick DNP Z68 film commercially available from DaiNippon Printing Co., Ltd. are suitable tie layers in many embodiments. Exemplary multilayer sheets have a so-called polymer multi-layer (PML) structure. According to the PML structure, a barrier sheet includes one or more dyads. Each dyad generally includes an inorganic dielectric layer supported upon a polymer layer. The inorganic dielectric layers may be any of the inorganic materials described herein, but often are oxides, nitrides, and/or carbides of silicon and/or aluminum. In some embodiments, the inorganic dielectric layers have thicknesses in the range from about 30 nm to about 100 nm. Polyester films are used as dyad substrates in many embodiments, but other polymer films may be used. Illustrative films may have thickness in the range from about 0.1 mm to several millimeters. To protect the films, the inorganic layers are formed at relatively low temperatures, e.g., 50° C. to about 60° C. could be suitable in some modes of practice.

In some products, the polymer substrates in each dyad are relatively thin, and the one or more dyads are supported upon a more substantial “master” substrate for product integrity. Polyester or other polymer films are also suitable for the master substrate. For each dyad, the polymer substrate provides a smooth surface to deposit the inorganic dielectric layer. Multiple dyads are stacked for enhanced barrier protection. Multiple dyads are used to minimize the risk that a defect in one dyad, e.g., a pinhole defect in a dielectric layer, would propagate to other dyads.

Examples of commercially available PML structures include FG100 film commercially available from Techni-Met, LLC, a subsidiary of Williams Advanced Materials, which is a subsidiary of Brush Engineered Materials Inc. and the 3M 2377 film commercially available from the 3M Company, St. Paul, Minn. PML barrier structures are further described in the following U.S. Pat. Nos. and patent publications: 7,486,019; 7,393,557; 7,351,479; 7,342,356; 7,300,859; 7,300,538; 7,276,291; 7,261,950; 7,186,465; 7,157,117; 7,140,741; 7,140,741; 7,067,405; 7,052,772; 7,018,713; 7,005,161; 6,960,393; 6,933,051; 6,929,864; 6,909,230; 6,887,346; 6,858,259; 6,838,183; 6,818,291; 6,811,829; 6,774,018; 6,706,412; 6,656,537; 6,649,433; 6,420,003; 6,627,267; 6,613,395; 6,594,134; 6,570,325; 6,544,600; 6,522,067; 6,509,065; 6,506,461; 6,497,924; 6,497,598; 6,492,026; 6,468,595; 6,451,947; 6,447,553; 6,441,553; 6,420,003; 6,413,645; 6,358,570; 6,309,508; 6,274,204; 6,270,841; 6,268,695; 6,264,747; 6,264,747; 6,231,939; 6,228,436; 6,228,434; 6,224,948; 6,218,004; 6,218,004; 6,217,947; 6,214,422; 6,207,239; 6,207,238; 6,118,218; 6,106,627; 6,092,269; 6,083,628; 6,066,826; 6,040,017; 6,010,751; 6,010,751; 5,945,174; 5,912,069; 5,902,641; 5,877,895; 5,811,183; 5,731,948; 5,725,909; 5,716,532; 5,681,666; 5,681,615; 5,654,084; 5,547,508; 5,440,446; 5,395,644; 5,260,095; 4,490,774; 2005-00176181A1; and 2007-0196682A1, each of which is incorporated herein by reference in its respective entirety for all purposes.

The present invention will now be described with reference to the following illustrative examples.

### Example 1

This example demonstrates that depositing a high WVTR silicone elastomer over CIGS-based cells protects cell efficiency and dramatically improves cell stability in damp environments.

### Cell Preparation

All cells used in this example were the same and included a metal substrate, back electrical contact, CIGS absorber, CdS buffer, TCO, and top electrical conduction grid of silver. The individual CIGS based solar cells were electrically configured by welding a 1×10 mm Sn-plated copper busbar on the right and left side of the cell which represents the positive and negative terminals of the device, respectively. The busbar material extends past the top edge of the solar cell materials by approximately 3 inches to facilitate the electrical testing and monitoring of the device. These individual CIGS based solar cells were cleaned in a 50% (vol) water:50% isopropanol alcohol (vol) solution at 25° C. by simple hand agitation for 30 seconds. This was followed by a 30 minute heating to 50° C. in an oven.

### Coating Formulations

In this example, three precursor products for forming elastomeric, polysiloxane polymer coatings were used. The 3-1765 Conformal Coating from Dow Corning Corporation, Midland, Mich. was used as received. The 3-1765 Conformal Coating from Dow Corning is solvent-less silicone, room temperature vulcanizable (RTV) coating. The material cures via hydrolysis/condensation of the alkoxy groups via available atmospheric moisture. The Sylgard® 184 Silicone Elastomer Kit from Dow Corning Corporation, Midland, Mich. was used as received. Sylgard® 184 Silicone Elastomer Kit and SE 1740 from Dow Corning are 2 part, solventless siloxanes that cure without generating by-products. Sylgard® 184 can be cured either at room temperature or thermally. SE 1740 requires a thermal cure. 10 parts of Part A was mixed with 1 part of Part B and applied to cells as described below.

SE 1740 from Dow Corning Corporation, Midland, Mich., was used as received. Equal amounts of Part A and Part B based on weight were mixed together and applied to cells as described below.

### Coating Application & Cure

The 3-1765 Conformal Coating product was applied to three CIGS-based cells (Samples 1-3) using a 15 mil gap (˜7.5 mil wet thickness) of a 8-Path wet film applicator from Paul N. Gardner Company, Inc, Pompano Beach, Fla. The coating was allowed to cure under laboratory ambient conditions for 4-5 hours. A 2^{nd} coat was applied using the 15 mil gap and allowed to cure at ambient lab conditions for at least seven days. Prior to coating, the electronic collection grids on the cells were exposed. The coatings completely covered the collections grids.

The Sylgard® 184 product was applied to 3 CIGS-based cells (Samples 4-6) using the 15 mil gap (˜7.5 mil wet thickness) of a 8-Path wet film applicator from Paul N. Gardner Company, Inc, Pompano Beach, Fla. The coating was allowed to cure under laboratory ambient conditions for 4-5 hours. The coated cells were then placed in an oven at 100° C. for 30 minutes. The coated cells were allowed to cool to lab temperature a 2^{nd} coat was applied using the 15 mil gap and cured in an oven at 100° C. for 30 minutes. Prior to coating, the electronic collection grids on the cells were exposed. The coatings buried the collections grids.

The SE 1740 product was applied to 3 CIGS-based cells (Samples 7-9) using the mil gap (˜7.5 mil wet thickness) of a 8-Path wet film applicator from Paul N. Gardner Company, Inc, Pompano Beach, Fla. The coated cells were placed in an oven at 80° C. for 30 minutes. The cells were allowed to cool to lab temperature and a 2^{nd} coat was applied using the 15 mil gap and cure at 80° C. for 30 minutes. After a couple of days the cells were placed in an oven at 100° C. for 30 minutes. Prior to coating, the electronic collection grids on the cells were exposed. The coatings buried the collections grids.

The following table reports cell efficiency (percentage) before and after incorporating an elastomeric coating onto the cells.

### Cell Efficiency Before & After Coating

| | | Efficiency | |
|---|---|---|---|
| | Initial | After | |
| | Efficiency | Coating | Change |
| Sample | (%) | (%) | (%) |
| 3-1765 | | | |
| 1 | 6.27 | 6.66 | 106 |
| 2 | 7.42 | 7.94 | 107 |
| 3 | 5.37 | 6.13 | 114 |
| SE 1740 | | | |
| 4 | 8.29 | 8.68 | 105 |
| 5 | 6.94 | 7.51 | 108 |
| 6 | 7.45 | 7.3 | 98 |
| Sylgard 184 | | | |
| 7 | 8.12 | 8.65 | 107 |
| 8 | 5.94 | 6.44 | 108 |
| 9 | 8.21 | 8.75 | 107 |

This illustrates that cell efficiency is at least substantially maintained and even increased after applying a siloxane coating.

### Example 2

The coated cells prepared in Example 1 were subjected to damp heat testing at 85° C. and 85% relative humidity (RH). Retained efficiency as a function of this exposure was evaluated. For comparison, uncoated cells also were tested.

The purpose of damp heat testing is to evaluate the ability of a sample to withstand the effect of long-term humidity exposure and penetration. The testing is carried out according to IEC 60068-2-78 (2001-08) except that the room temperature cells were introduced into the testing chamber without preconditioning. Also, the following severities were applied:

Test temperature: 85° C. +/−2° C.

### Relative Humidity: 85%+/−5%

Test duration 1107 hr

The retained efficiency as a function of exposure is shown in the following table. All tabulated values are an average of three samples unless otherwise noted. A single data point was obtained for some of the cells due to the adhesive failing which attached the busbar to the cell.

| | % Retained Efficiency as function of time | | | | |
|---|---|---|---|---|---|
| Coating | 285 hr | 535 hr | 785 hr | 947 hr | 1107 hr |
| 3-1765 | 113 | 85 | 72 | 103* | 79* |
| Sylgard 184 | 110 | 84 | 54 | 76 | 62 |
| SE 1740 | | 51 | 14 | 53 | 45 |
| Bare Cell (no | | 32 (500 hr) | | | 3 (1000 hr) |
| coating or | | | | | |
| barrier film) | | | | | |

*Single data point

For the bare cell (no coating), the conductive adhesive used to adhere the electrical leads failed leading to corrosion of the cell in the areas not coated with the siloxane coatings. These data also illustrate that an uncoated cell fails quickly in the damp heat testing.

### Example 3

### Cell Preparation

All cells used in this example were the same except for the comparison as noted below. Each cell included a metal substrate, back electrical contact, CIGS absorber, CdS buffer, TCO, and top electrical conduction grid of silver. The individual CIGS based solar cells were electrically configured by welding a 1×10 mm Sn-plated copper busbar on the right and left side of the cell which represents the positive and negative terminals of the device. The busbar material extends past the top edge of the solar cell materials by approximately 3 inches to facilitate the electrical testing and monitoring of the device. These individual CIGS based solar cells were cleaned in a 50% (vol) water:50% isopropanol alcohol (vol) solution at 25° C. by simple hand agitation for 30 seconds. This was followed by a 30 minute heating to 50° C. in an oven.

### Coating Formulations

The 3-1765 Conformal Coating product from Dow Corning Corporation, Midland, Mich. was used as received.

The Sylgard® 184 Silicone Elastomer Kit from Dow Corning Corporation, Midland, Mich. was formulated as follows:
85 g of Sylgard 184 Part A was combined with 50 g of toluene in a glass jar. The blend was mixed until homogenous; and
8.5 g of Sylgard Part B was added to the glass jar and mixed until homogenous.

### Coating Application

The 3-1765 Conformal Coating product was added to a glass jar and spray applied to 12 CIGS cells (held in a vertical orientation) using a Preval® Sprayer, supplied by Preval Sprayer Division of Precision Valve Corporation, Yonkers, N.Y., to achieve a final dry film thickness of at least 3 mils.

Sylgard 184 coating formulation described above was spray applied to 12 CIGS cells (held in a vertical orientation) using a Preval® Sprayer, supplied by Preval Sprayer Division of Precision Valve Corporation, Yonkers, N.Y. to achieve a dry film thickness of at least 3 mils.

### Cure

All of the coated cells were cured while being held in a horizontal orientation under ambient lab conditions for 72 hours and then heat cured with this same orientation at 100° C. for 1 hour.

### Lamination

The cells were incorporated into laminated structures in which additional protective barrier films were laminated over the elastomeric coating. Two protective barrier films were used. These were the Techni-Met FG100 barrier film and the 3M 2377 film (hereinafter 3M) commercially available from the 3M Company. For each barrier film, a thermoplastic polyolefin film having the trade designation DNP Z68 film (hereinafter DNP) commercially available from Dai Nippon Printing Co., Ltd. was used to enhance adhesion of the protective barrier film to the underlying elastomer layer. Although the protective barrier over the overlying elastomer varied among the samples, the same kind of barrier structure was also laminated to the backside of the cells so that all the cells were identical except for the nature of the elastomer coated over the collection grids and the protective barrier coated over the elastomer.

Generally, to carry out the lamination, all of the components of the structure to be laminated were cut to the same size for ease of alignment. Teflon paper was used as a release liner on both the bottom and top of the stack to be laminated. First, the films of the backside protection structure were stacked onto a Teflon sheet for each sample. In order from bottom to top, these layers included a TPO membrane (45 mil Firestone TPO membrane), a tie layer (DNP Z68 material), a backsheet layer (222 micrometer Protekt TFB HD barrier film from Madico of Woburn, Mass., USA), and an encapsulant/tie layer (DNP Z68 material). The CIGS-based cell coated with elastomer is then placed onto the stack with the elastomer facing up. Then the layers of the barrier structure and desired encapsulant/tie layers were added to the stack in the desired order. A second Teflon sheet was applied over the stack. The stack was then laminated to complete the structure. Lamination occurred at a set temperature of 150° C., and the registered temperature at the heating platen was about 143° C. The laminator was closed with no pressure applied. A vacuum is pulled for 5 minutes with the flexible membrane in the “up position”. Then, the pressure is ramped to 101 kPa which allows the flexible membrane to initiate contact with the structure. A slow ramp to 12 kPa occurred for about 21 seconds. Then a medium rate ramp occurred to about 40 kPa for about 23 seconds. A fast ramp to 101 kPa occurred for 16 seconds. The lamination pressure was maintained at 101 kPa for 6 minutes. The laminator was then opened. The finished structure is removed.

The various structures from the elastomer coating through the upper barrier structure are reported in the following table for each sample in order from bottom-most layer (on the left of the list below) to the top most layer (on the right of the listing below). The structure from the CIGS cell itself to the bottom most layer of the stack was the same for all the samples.

For comparison (Sample G), a laminated structure was built with the same layers as the other samples except for the elastomer coating. Sample G was generally of a similar construction as the other CIGS-based cells tested (which were 3 15/16 inches×8¼ inches) except that the comparison cell had reduced area of about 1 5/16 to 1⅝ inches×7¼ inches and the busbar was connected differently. The reduced size of Sample G and the different busbar connection should not impact performance characteristics evaluated in this Example.

| Sample 1D | Elastomer and Barrier Structure |
|---|---|
| A | 3-1765 + DNP + Techni-met FG100 |
| B | 3-1765 + DNP + 3M |
| C | 3-1765 + 3M + DNP + 3M |
| D | Sylgard 184 + DNP + Techni-met FG100 |
| E | Sylgard 184 + DNP + 3M |
| F | Sylgard 184 + DNP + 3M + DNP + 3M |
| G | Smaller PV cell + DNP + FG100 |
| | (Comparison) |

### Damp Heat (85° C./85% RH) Exposure Results

The samples were subjected to the damp heat testing protocol of Example 2. The retained efficiency as a function of exposure is shown in the following table. All tabulated values are an average of three samples unless otherwise noted.

| | % Retained Initial Efficiency | | | | |
|---|---|---|---|---|---|
| Sample 1D | 1000 hr* | 1500 hr* | 2000 hr* | 2500 hr | 3000 hr |
| A | 64 | 63 | 59 | 47* | 25* |
| B | 85 | 88 | 84 | 80* | 66* |
| C | 79 | 87 | 85 | 83* | 84* |
| D | 78 | 74 | 68 | 58± | 46 [symbol] |
| E | 120 | 140 | 132 | 127* | 93± |
| F | 116 | 121 | 119 | 109* | 114* |
| G | 82 | 75 | 47 | 35 | |

≧80% retained efficiency illustrates the robustness and durability of the structure.
*Average of 3 cells
±Average of 2 cells [symbol]
Single cell data point

Other embodiments of this invention will be apparent to those skilled in the art upon consideration of this specification or from practice of the invention disclosed herein. Various omissions, modifications, and changes to the principles and embodiments described herein may be made by one skilled in the art without departing from the true scope and spirit of the invention which is indicated by the following claims.

What is claimed is:

1. A photovoltaic device having a light incident surface and a backside surface, said device also comprising:
a) a chalcogenide-containing photovoltaic layer comprising at least one of copper, indium and/or gallium;
b) a transparent conductive layer interposed between the photovoltaic layer and the light incident surface, wherein the transparent conductive layer is electrically coupled to the photovoltaic layer;
c) an electronic collection grid electrically coupled to the transparent conductive layer and overlying at least a portion of the transparent conductive layer;
d) an elastomeric structure having a light incident surface, said structure overlying at least portions of the electronic collection grid and the transparent conductive layer in a manner such that the light incident surface of the elastomeric structure is spaced apart from a major portion of the conductor, and wherein the elastomeric structure comprises an elastomeric siloxane polymer having a WVTR of at least 0.1 g/m²-day and
e) an optional protective barrier overlying the elastomeric structure.

2. The device of claim 1, wherein the elastomeric structure has a WVTR in the range from about 0.5 g/m²-day to about 500 g/m²-day.

3. The device of claim 2, wherein the elastomeric structure has a WVTR in the range from about 0.5 g/m²-day to about 150 g/m²-day

4. The device of claim 1, wherein the elastomeric structure comprises a siloxane polymer that is formed in situ from ingredients comprising one or more siloxane precursors.

5. The device of claim 4, wherein the elastomeric structure comprises a siloxane polymer that is formed in situ from ingredients comprising a first siloxane precursor having Si-alkenyl functionality and a second precursor having silicon hydride functionality.

6. The device of claim 4, wherein the elastomeric structure comprises a siloxane polymer that is formed in situ from an alkoxy functional siloxane precursor.

7. The device of claim 6, wherein the siloxane polymer is formed in situ from at least the alkoxy functional siloxane precursor using room temperature vulcanization techniques.

8. The device of claim 1, wherein the electronic collection grid comprises Ag, Ni, Cu or Al or combinations thereof.

9. The device of claim 1, wherein the light incident surface of the elastomeric structure is spaced apart from the electrical conductors by a depth in the range from about 0.5 mils to about 50 mils.

10. The device of claim 1, wherein the device includes the protective barrier and wherein the protective barrier comprises an inorganic dielectric composition.

11. The device of claim 1, wherein the device includes the protective barrier and wherein the protective barrier comprises an oxide, nitride, carbide, or combinations thereof of at least one of silicon and aluminum.

12. The device of claim 1, wherein the device includes the protective barrier and wherein the protective barrier has a multilayer structure comprising at least one dyad supported on a substrate wherein, each dyad independently comprises an inorganic composition layer and an organic composition layer.

13. The device of claim 12, wherein the inorganic composition comprises an inorganic dielectric composition.

14. The device of claim 13, wherein the inorganic dielectric composition is selected from an oxide, carbide, and/or nitride of silicon, titanium and/or aluminum.

15. The device of claim 12, wherein the protective barrier comprises a plurality of said dyads.

16. The device of claim 12, wherein the dyad substrate comprises a polymer film.

17. The device of claim 16, wherein the polymer film comprises polyester.
